(19) United States
(12) Patent Application Publication
(10) Pub. No.: US 2009/0263934 A1
(43) Pub. Date: Oct. 22, 2009

(54) METHODS OF FORMING CHALCOGENIDE FILMS AND METHODS OF MANUFACTURING MEMORY DEVICES USING THE SAME

(75) Inventors: Hyeong-Geun AN, Hwaseong-si (KR); Ran-Young KIM, Yuseong-gu (KR); Soon-Gil YOON, Yuseong-gu (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/255,734

(22) Filed: Oct. 22, 2008

(30) Foreign Application Priority Data
Apr. 22, 2008 (KR) 2008-37142
Sep. 22, 2008 (KR) 2008-92855

(51) Int. Cl. H01L 45/00; B05D 5/12

(52) U.S. Cl. 438/102; 427/126.1; 257/E45.002

(57) ABSTRACT

A method of forming a chalcogenide film is provided which includes forming a germanium film on a substrate by exposing the substrate to a germanium source and a first antimony source, and growing a polynary film from the germanium film by exposing the germanium film to at least one of a tellurium source and a second antimony source.

### PRIORITY STATEMENT

A claim of priority under 35 U.S.C § 119 is made to Korean Patent Application No. 10-2008-0037142, filed Apr. 22, 2008, and to Korean Patent Application No. 10-2008-0092855, filed Sep. 22, 2008. The entirety of both priority applications is herein incorporated by reference.

### SUMMARY

The present invention generally relates to the formation of a chalcogenide film which includes, for example, antimony (Sb), germanium (Ge), and/or tellurium (Te).

Chalcogenide films are utilized, for example, as the phase-change material layer of phase-change memory devices. Each unit memory cell of a phase-change memory device is programmable in at least two material phase states, i.e., a crystalline state which exhibits a relatively low resistance and an amorphous state which exhibits a relatively high resistance. Programming is achieved by subjecting the chalcogenide film of the memory cell to different thermal conditions, typically induced by joule heating and cooling.

As mentioned above, the present invention generally relates to the formation of a chalcogenide film. For example, in one aspect of the invention, a method of forming a chalcogenide film is provided which includes forming a germanium film on a substrate by exposing the substrate to a germanium source and a first antimony source, and growing a polynary film from the germanium film by exposing the germanium film to at least one of a tellurium source and a second antimony source.

The present invention also generally relates to the fabrication of a memory device. For example, in another aspect of the invention, a method of fabricating a memory device is provided which includes forming an insulating layer which includes an opening that exposes a bottom electrode, forming a chalcogenide pattern which fills the opening, and forming a top electrode on the chalcogenide pattern. The formation of the chalcogenide pattern includes forming a germanium film within the opening by exposing the opening to a germanium source and a first antimony source, and growing a polynary film from the germanium film by exposing the germanium film to at least one of a tellurium source and a second antimony source.

### BRIEF DESCRIPTION OF THE DRAWINGS

The above and other aspects and features of the present invention will become readily apparent from the detailed description that follows, with reference to the accompanying drawings, in which:

FIG. 1 is a flowchart for reference in describing a method of forming a chalcogenide thin film according to an embodiment of the present invention;

FIGS. 2A through 2C are cross-sectional views for reference in describing a method of forming a chalcogenide thin film according to an embodiment of the present invention;

FIG. 3 is an exemplary view of a deposition apparatus for forming a chalcogenide thin film according to an embodiment of the present invention;

FIG. 4A is a graph of X-ray diffraction (XRD) data of a unary thin film of germanium (Ge) formed according to an embodiment of the present invention;

FIG. 4B is a graph of data measured by Auger electron spectroscopy (AES) of a unary thin film of germanium (Ge) according to the embodiment of the present invention;

FIG. 4C is a graph of a deposition rate of a unary thin film of germanium (Ge) according to the embodiment of the present invention;

FIG. 5A is a graph of X-ray diffraction (XRD) data of a binary thin film of Ge—Te formed according to an embodiment of the present invention;

FIG. 5B is a graph of data measured by Auger electron spectroscopy (AES) of a binary thin film of Ge—Te according to the embodiment of the present invention;

FIG. 6 is a graph of X-ray diffraction (XRD) data of a ternary thin film of Ge—Te—Sb formed according to an embodiment of the present invention;

FIGS. 7A through FIG. 7E are cross-sectional views for reference in describing a method of fabricating a memory device according to an embodiment of the present invention;

FIG. 8 is a transmission electron microscope (TEM) photograph of a phase-change material according to an embodiment of the present invention; and

FIGS. 9A and 9B are cross-sectional views for reference in describing a method of fabricating a memory device according to another embodiment of the present invention.

### DETAILED DESCRIPTION OF EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

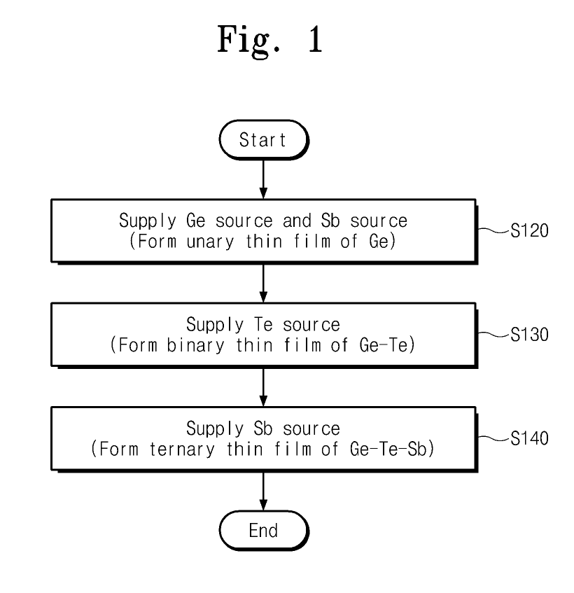

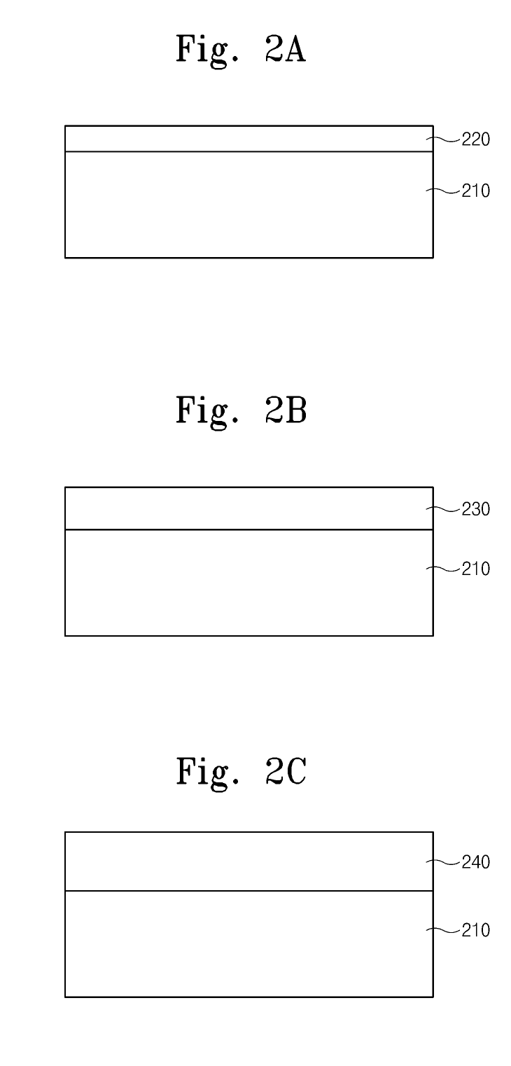

A method of forming a chalcogenide thin film according to an exemplary and non-limiting embodiment of the present invention will now be described with reference to FIG. 1 and FIGS. 2A through 2C.

Referring to FIGS. 1 and 2A, a first antimony (Sb) source and germanium (Ge) source are supplied to form a germanium thin film 220 on a substrate 210 (S1200).

The germanium source may, for example, be one or more selected from the group consisting of (CH₃)₄Ge, (C₂H₅)₄Ge, (n-C₄H₉)₄Ge, (i-C₄H₉)₄Ge, (C₆H₅)₄Ge, (CH₂=CH)₄Ge, (CH₂CH=CH₂)₄Ge, (CF₂=CF)₄Ge, (C₆H₅CH₂CH₂CH₂)₄Ge, (CH₃)₃(C₆H₅)Ge, (CH₃)₃(C₆H₅CH₂)Ge, (CH₃)₂(C₂H₅)₂Ge, (CH₃)₂(C₆H₆)₂Ge, CH₃(C₂H₅)₃Ge, (CH₃)₃(CH=CH₂)Ge, (CH₃)₃(CH₂CH=CH₂)Ge, (C₂H₅)₃(CH₂CH=CH₂)Ge, (C₂H₅)₃(C₅H₅)Ge, (CH₃)₃GeH, (C₂H₅)₃GeH, (C₃H₇)₃GeH, Ge(N(CH₃)₂)₄, Ge(N(CH₃)(C₂H₅))₄, Ge(N(C₂H₅)₂)₄, Ge(N(i-C₃H₇)₂)₄, and Ge[N(Si(CH₃)₃)₂]₄.

The first antimony source may, for example, be one or more selected from the group consisting of Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃. Sb(N(CH₃)(C₂H₅))₃, Sb(N(C₂H₅)₂)₃, Sb(N(i-C₃H₇)₂)₃, and Sb[N(Si(CH₃)₃)₂]₃.

The germanium thin film 220 may, for example, be formed by metal organic chemical vapor deposition (MOCVD). The germanium source and the first antimony source may be simultaneously supplied into an atmosphere containing the substrate 210.

The germanium thin film 220 may be formed to selectively include germanium, while does not include antimony. In other words, the germanium thin film 220 may be an antimony-free (Sb-free) unary thin film. The first antimony source does not constitute the germanium thin film 220, but may assist deposition of the germanium thin film 220. Decomposition of the germanium source is an exothermic reaction, and that of the first antimony source is an endothermic reaction. Thus, interaction between decompositions of the sources may be allowed to expedite the decomposition of the germanium source and the deposition of the germanium thin film 220.

The deposition rate of the germanium thin film 220 may be controlled by controlling a flow rate of the germanium source and the first antimony source. Since the first antimony source serves to expedite growth of the germanium thin film 220, the deposition rate of the germanium thin film 220 may become higher as an amount of the first antimony source is increased. However, if the amount of the first antimony source is greater than that of the germanium source, antimony particles may be generated by aggregation of antimony atoms. The antimony particles may remain on the germanium thin film 220 to make a surface of the germanium thin film 220 uneven. That is, the germanium thin film 220 may be degraded. Therefore, the amount of the first antimony source provided may be smaller than that of the germanium source.

Referring to FIGS. 1 and 2B, a tellurium source may be provided to the germanium thin film 220 to form a binary thin film 230 of germanium and tellurium on the substrate 210 (S130). The tellurium source may be one selected from the group consisting of Te(CH₃)₂, Te(C₂H₅)₂, Te(n-C₃H₇)₂, Te(i-C₃H₇)₂, Te(t-C₄H₉)₂, Te(i-C₄Hg)₂, Te(CH₂=CH)₂, Te(CH₂CH=CH₂)₂, and Te[N(Si(CH₃)₃)₂]₂.

The binary thin film 230 may be formed by means of, for example, metal organic chemical vapor deposition (MOCVD). Providing the tellurium source may allow the unary thin film 220 of germanium to grow into a binary thin film 230 of germanium and tellurium. That is, the binary thin film 230 may include germanium and tellurium which constitute a single layer, not separated layers.

Referring to FIGS. 1 and 2C, a second antimony source may be provided to the binary thin film 230 to form a ternary thin film 240 of germanium, tellurium, and antimony on the substrate 210 (S140). The second antimony source may be one selected from the group consisting of Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃, Sb(N(i-C₃H₇)₂)₃, and Sb[N(Si(CH₃)₃)₂]₃.

The ternary thin film 240 may be formed by means of, for example, metal organic chemical vapor deposition (MOCVD). Providing the second antimony source may allow the binary thin film 230 to grow into a ternary thin film 240 of germanium, tellurium, and antimony. That is, the ternary thin film 240 may include germanium, tellurium, and antimony which constitute a single layer, not separated layers.

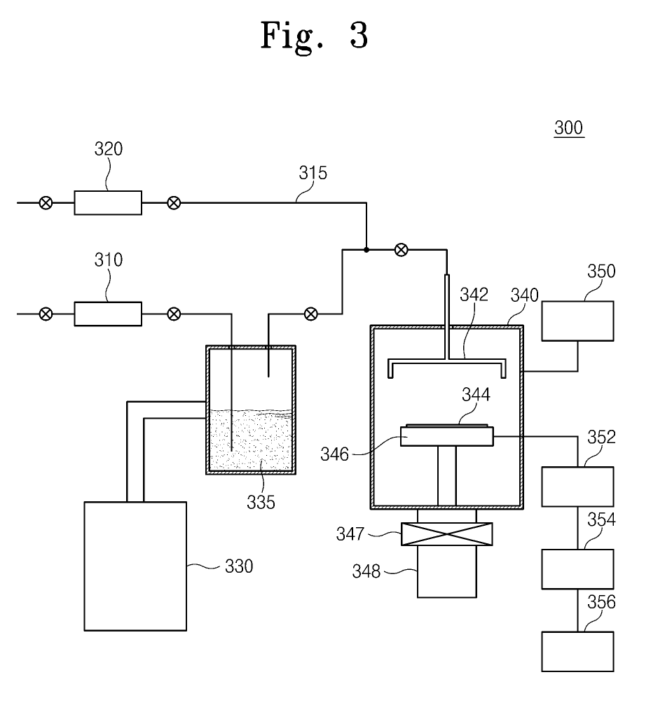

A deposition apparatus 300 that may be utilized to form a chalcogenide thin film according to an exemplary embodiment of the present invention will now be described below in detail with reference to FIG. 3.

The deposition apparatus 300 of this example includes a carrier supply unit 310 configured to supply carrier material and a bubbler 335 in which source materials are contained. The carrier supply unit 310 and the bubbler 335 are connected to each other by supply pipes 315, and the bubbler 335 is connected to a cooling system 330. A plurality of bubblers, corresponding in number to the number of the source materials, may be provided between the carrier supply unit 310 and a chamber 340. A flow rate of the source materials is controlled by controlling a temperature of the bubbler 335 or the amount of the carrier material. The source materials are carried into the chamber 340 by the carrier material.

The supply pipes 315 are connected to the chamber 340 where a thin film is formed. The source material is supplied into the chamber 340 through the supply pipes 315 without being mixed or after being mixed. A valve or the like may be mounted on the supply pipes 315 to control a flow rate of gas supplied into the chamber 340.

The chamber 340 includes a shower head 342, a susceptor 344, and a heater 346 therein. The shower head 342 is disposed at an upper portion within the chamber 340, and the susceptor 344 is disposed at a lower portion within the chamber 340 to face the shower head 342. The source materials flowing through the respective supply pipes 315 may meet one another before arriving at the shower head 342. The source materials supplied into the chamber 340 are sprayed towards the susceptor 344 which is installed at the center within the chamber 340, on which a substrate is loaded. The heater 346 is installed in a base for supporting the susceptor 344 and increases a temperature of a substrate (or wafer) loaded on the susceptor 344. The chamber 340 may further include an outlet (not shown) formed to exhaust gases generated or used inside the chamber 340.

The deposition apparatus 300 of this example further includes a pressure gage 350 configured to check an internal pressure of the chamber 340, a thermometer 352 configured to measure a temperature of the heater 346, a controller 354 configured to control the temperature of the heater 346, and a power supply unit 356 configured to supply a power to the heater 346.

The deposition apparatus 300 of this example further includes a reactive gas supply unit 320 configured to supply other reactive gases.

A method of forming chalcogenide thin films according to an exemplary embodiment of the present invention and characteristics of the thin films formed thereby will now be described below in detail.

A germanium thin film may be formed on a substrate. There may be a conductive layer (e.g., titanium aluminum nitride (TiAIN) layer) on the substrate (e.g., silicon wafer). The germanium thin film may, for example, be formed by means of the deposition apparatus 300 described in FIG. 3. The germanium thin film may be formed using a germanium source and a first antimony source. The germanium source may, for example, be one selected from the group consisting of (CH₃)₄Ge, (C₂H₅)₄Ge, (n-C₄H₉)₄Ge, (i-C₄H₉)₄Ge, (C₆H₅)₄Ge, (CH₂=CH)₄Ge, (CH₂CH=CH₂)₄Ge, (CF₂=CF)₄Ge, (C₆H₅CH₂CH₂CH₂)₄Ge, (CH₃)₃(C₆H₅)Ge, (CH₃)₃(C₆H₅CH₂)Ge, (CH₃)₂(C₂H₅)₂Ge, (CH₃)₂(C₆H₅)₂Ge, CH₃(C₂H₅)₃Ge, (CH₃)₃(CH=CH₂)Ge, (CH₃)₃(CH₂CH=CH₂)Ge, (C₂H₅)₃(CH₂CH=CH₂)Ge, (C₂H₅)₃(C₅H₅)Ge, (CH₃)₃GeH, (C₂H₅)₃GeH, (C₃H₇)₃GeH, Ge(N(CH₃)₂)₄, Ge(N(CH₃)(C₂H₅))₄, Ge(N(C₂H₅)₂)₄, Ge(N(i-C₃H₇)₂)₄, and Ge[N(Si(CH₃)₃)₂]₄. The first antimony source may be one selected from the group consisting of Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃. Sb(N(i-C₃H₇)₂)₃, and Sb[N(Si(CH₃)₃)₂]₃. An inert material such as argon may be used as carrier materials to carry the source materials. The amount of vaporized gas of the respective materials may be controlled by means of a cooling system 330.

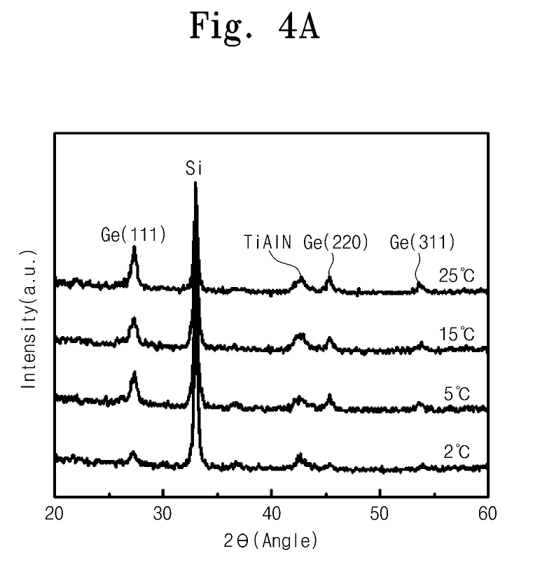

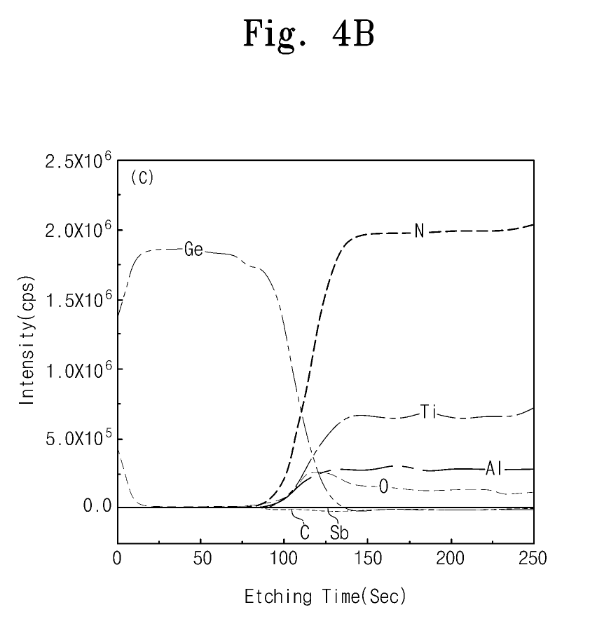

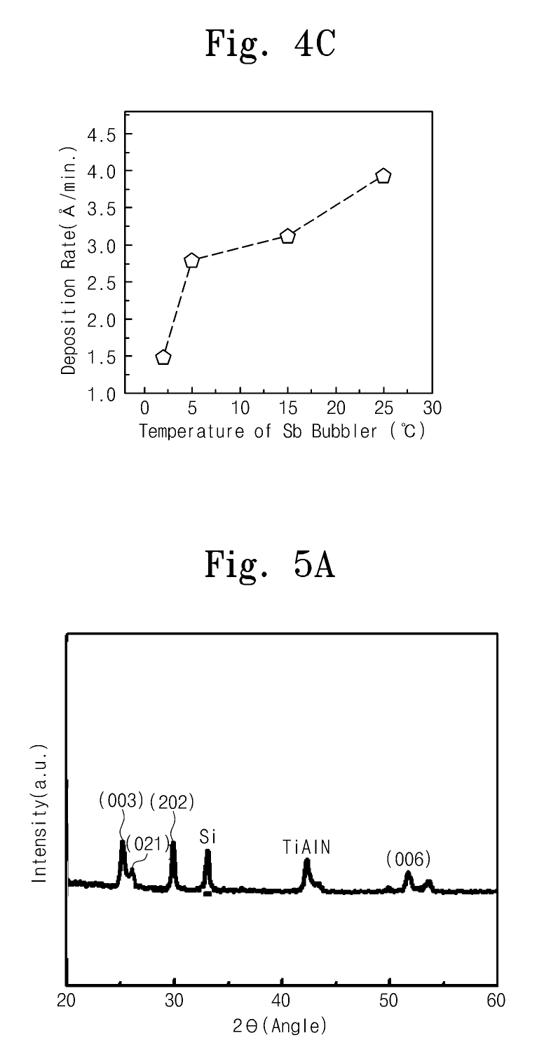

Characteristics of a germanium thin film according to an exemplary embodiment of the present invention will now be described with reference to FIGS. 4A through 4C. In this exemplary embodiment, provided was a silicon substrate where a TlAlN layer is formed; Ge(allyl)₄ was used as a germanium source; Sb(iPr)₃ was used as a first antimony source; argon was used as a carrier material; an injection rate of the argon gas was about 30 sccm; an inner temperature of a bubbler 335 for the germanium source was about 50° C.; an inner temperature of a bubbler 335 for the first antimony source was about 2, 5, 15 or 25° C.; during the formation of the germanium thin film, an inner pressure of a chamber 340 was maintained at about 5 Torr and a temperature of a heater 346 inside the chamber 340 was maintained at about 400° C.; a process of forming the thin film was performed for about 4 hours; and a temperature of supply pipes 315 was maintained at about 70° C. to prevent the materials from condensing while the materials are carried to the chamber 340.

X-ray diffraction (XRD) characteristics of germanium thin films formed based on temperatures of the bubbler 335 including Sb(iPr)₃ will be described with reference to FIG. 4A. XRD data was measured by means of a θ-2θ method using D/MAX-RC (Rigaku, Japan). A depth profile of the germanium thin film will be described with reference to FIG. 4B. The depth profile was measured by means of Auger electron spectroscopy (AES) using a 310-D System (VG Scientific Microlab, UK). A deposition rate of germanium thin films formed based on temperatures of the bubbler 335 including Sb(iPr)₃ will be described with reference to FIG. 4C.

Referring to FIGS. 4A through 4C, a peak of the germanium becomes strong as a temperature of the bubbler 335 including Sb(iPr)₃ increases (see FIG. 4A). However, there are no measurable antimony atoms in the germanium thin film (see FIG. 4B). That is to say, the germanium thin film is substantially free of antimony. A deposition rate of the germanium thin film increases as a temperature of the bubbler 335 including Sb(iPr)₃ increases (see FIG. 4C). An amount of the Sb(iPr)₃ supplied into a reaction chamber may increase as the temperature of the bubbler 335 including Sb(iPr)₃ increases. That is, while antimony of the Sb(iPr)₃ is not deposited, the Sb(iPr)₃ may expedite deposition of the germanium thin film.

Although not illustrated, if only a germanium source (e.g., Ge(ally)₄) is supplied without supplying the first antimony source (e.g., Sb(iPr)₃), a germanium thin film may not be formed.

The above-described germanium thin film may grow into a binary thin film of germanium and tellurium. The binary thin film may be formed using a tellurium source which is supplied into the chamber 340. The tellurium source may, for example, be one selected from the group consisting of Te(CH₃)₂, Te(C₂H₅)₂, Te(n-C₃H₇)₂, Te(i-C₃H₇)₂, Te(t-C₄H₉)₂, Te(i-C₄H₉)₂, Te(CH₂=CH)₂, Te(CH₂CH=CH₂)₂, and Te[N(Si(CH₃)₃)₂]₂.

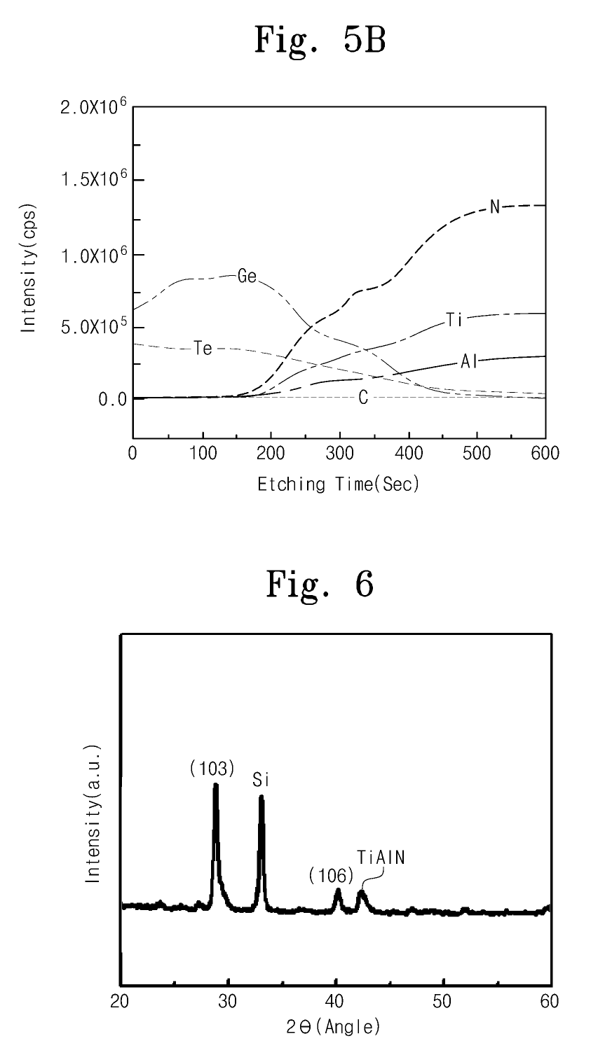

Characteristics of the binary thin film will be described with reference to FIGS. 5A and 5B. In this exemplary embodiment, Te(tBu)₂ was used as a tellurium source, and argon gas was used as carrier material to carry the Te(tBu)₂. A temperature of the Te(tBu)₂ bubbler was maintained at about 30° C., and the argon gas was injected into the chamber 340 at about 30 sccm. During the formation of the binary thin film, an inner pressure of the chamber 340 was maintained at about 3 Torr and the binary thin film was deposited at a temperature of about 290° C. for about 2 hours. The binary thin film was formed by reacting tellurium atoms with the germanium thin film. If a deposition temperature is excessively low, a reaction speed of the tellurium with the germanium thin film may be lowered, thus making it difficult or time intensive to form the binary thin film. At the above pressure, a deposition temperature may be controlled to as low as about 250° C. to enhance reactivity of the tellurium.

X-ray diffraction (XRD) characteristics of the binary thin film will be described with reference to FIG. 5A, and a depth profile of the binary thin film will be described with reference to FIG. 5B.

Referring to FIG. 5A, the binary thin film of Ge—Te exhibits a rhombohedral structure. FIG. 5A does not show a peak corresponding to the unary germanium film as shown in FIG. 4A. Referring to FIG. 5B, a thin film formed by means of the above-described method is a single layer in which germanium and tellurium coexist. That is to say, the thin film is not a tellurium thin film that is separately formed on a germanium thin film.

The binary thin film formed by means of the above-described method may grow into a ternary thin film of germanium, tellurium, and antimony. The ternary thin film may be formed using a second antimony source. The second antimony source may be supplied into the chamber 340. The second antimony source may include one selected from the group consisting of Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃. Sb(N(i-C₃H₇)₂)₃, and Sb[N(Si(CH₃)₃)₂]₃.

Characteristics of the ternary thin film will be described with reference to FIG. 6, which is a graph of X-ray diffraction (XRD) data of a ternary thin film of Ge—Te—Sb formed according to an embodiment of the present invention. In this exemplary embodiment, Sb(iPr)₃ source was used as the second antimony source. A temperature of the Sb(iPr)3 bubbler was maintained at about 30° C. Argon gas, as carrier material, used to carry the Sb(iPr)3, was injected into the chamber 340 at about 30 sccm. During the formation of the ternary thin film, an inner pressure of the chamber 340 was maintained at about 5 Torr. The ternary thin film was deposited at a temperature of about 310° C. for about 2 hours.

Referring to FIG. 6, the ternary thin film exhibits a hexagonal structure. FIG. 6 does not show peaks corresponding to the unary germanium film or the binary film. It can thus be seen that a ternary thin film has grown from the binary thin film of the rhombohedral structure.

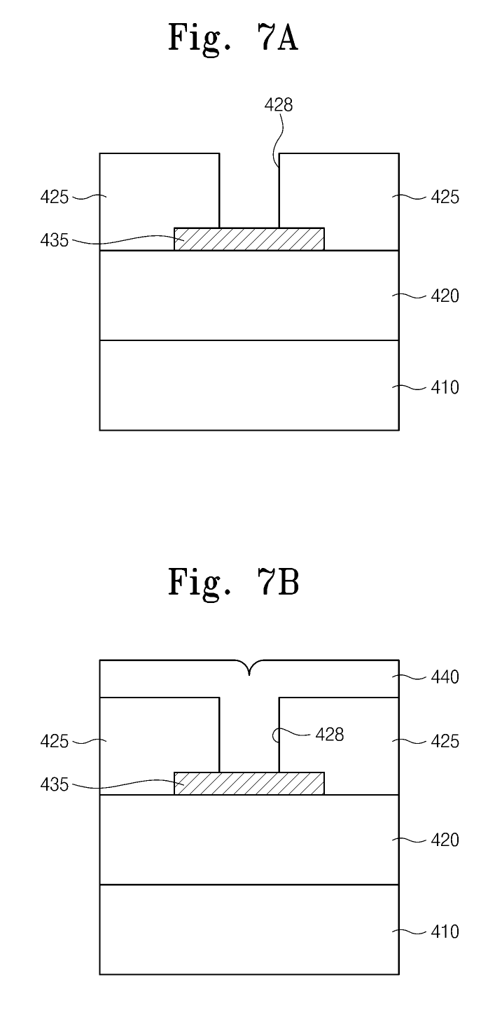

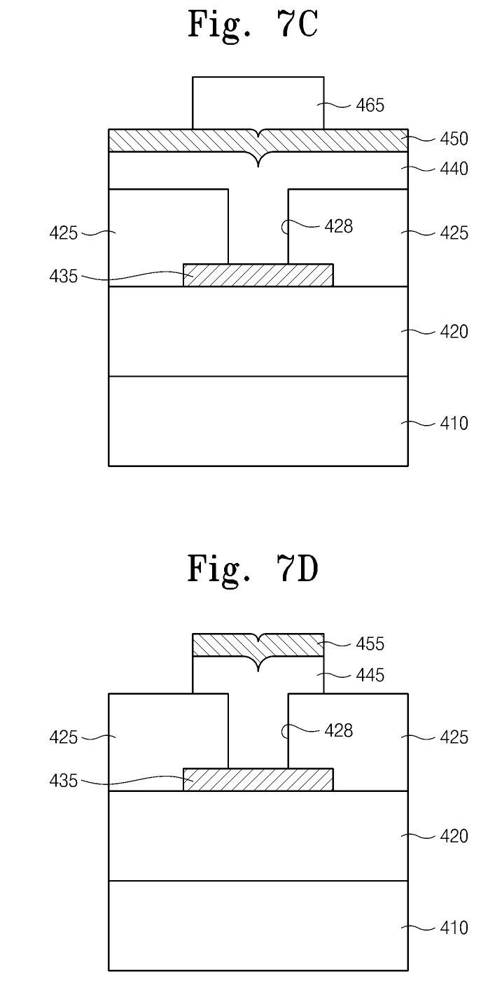

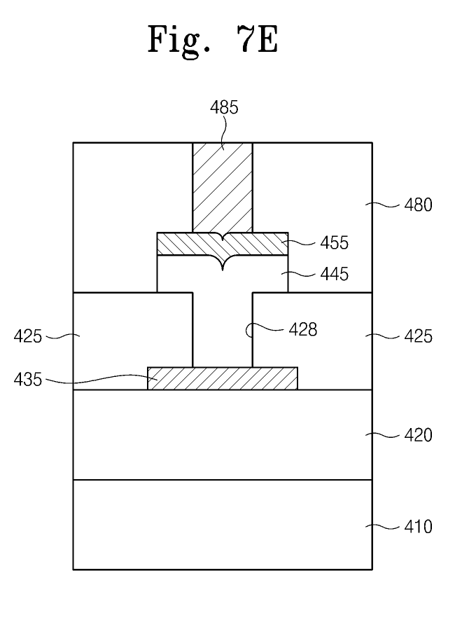

A method of fabricating a memory device including a chalcogenide thin film according to an exemplary embodiment of the present invention will now be described below in detail with reference to the cross-sectional examples of FIGS. 7A through 7E.

Referring to FIG. 7A, a first interlayer dielectric 420 is formed on a substrate 410, and a bottom electrode 435 is formed on the first interlayer dielectric 420. The bottom electrode 435 includes, for example, at least one selected from the group consisting of titanium nitride (TiN), tantalum nitride (TaN), molybdenum nitride (MoN), niobium nitride (NbN), titanium silicon nitride (TISiN), titanium aluminum nitride (TiAIN), titanium boron nitride (TiBN), zirconium silicon nitride (ZrSiN), tungsten silicon nitride (WSiN), tungsten boron nitride (WBN), zirconium aluminum nitride (ZrAIN), molybdenum silicon nitride (MoSiN), molybdenum aluminum nitride (MoAIN), tantalum silicon nitride (TaSiN), tantalum aluminum nitride (TaAIN), titanium oxynitride (TiON), titanium aluminum oxynitride (TiAION), tungsten oxynitride (WON), and tantalum oxynitride (TaON).

The bottom electrode 435 may, for example, be formed by means of stacking using physical vapor deposition (PVD) or chemical vapor deposition (CVD) and a patterning processes.

A second interlayer dielectric 425 is formed on the bottom electrode 435. The second interlayer dielectric 425 is patterned to form an opening 428 to expose a portion of the bottom electrode 425 within the second interlayer dielectric 425.

Referring to FIG. 7B, a phase-change material layer 440 is formed on the second interlayer dielectric 425. The phase-change material layer 440 includes a chalcogenide compound, and includes tellurium (Te), germanium (Ge), and/or antimony (Sb). The phase-change material layer 440 is formed, for example, by metal organic chemical vapor deposition (MOCVD) as described above, at a pressure, for example, of about 10 Torr or less.

The phase-change material 440 is formed in the opening 428 and on the second interlayer dielectric 425. In this example, the opening 428 is filled with the phase-change material layer 440.

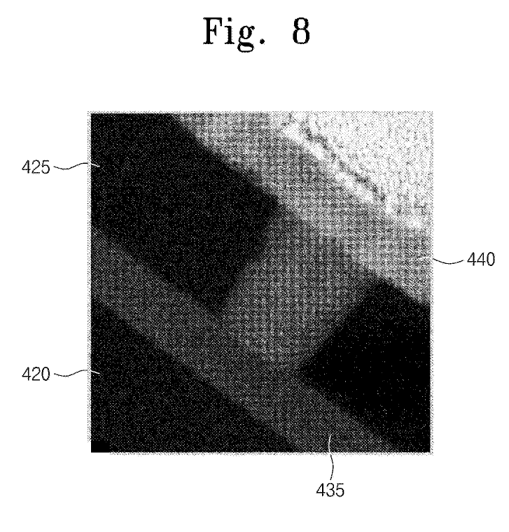

FIG. 8 is a transmission electron microscope (TEM) photograph of a phase-change material layer 440. In particular, referring to FIG. 8, the phase-change material layer 440 was formed in the opening 428 to exhibit favorable step coverage. Also, a composition ratio of the phase-change material layer 440 filling the opening 428 was uniform along a depth of the opening 428.

Referring to FIG. 7C, a conductive layer 450 is formed on the phase-change material layer 440. The conductive layer 450 includes, for example, at least one selected from the group consisting of titanium nitride (TiN), tantalum nitride (TaN), molybdenum nitride (MoN), niobium nitride (NbN), titanium silicon nitride (TiSiN), titanium aluminum nitride (TIAIN), titanium boron nitride (TiBN), zirconium silicon nitride (ZrSiN), tungsten silicon nitride (WSiN), tungsten boron nitride (WBN), zirconium aluminum nitride (ZrAIN), molybdenum silicon nitride (MoSiN), molybdenum aluminum nitride (MoAIN), tantalum silicon nitride (TaSiN), tantalum aluminum nitride (TaAIN), titanium oxynitride (TiON), titanium aluminum oxynitride (TiAION), tungsten oxynitride (WON), and tantalum oxynitride (TaON).

The conductive layer 450 may be formed of the same material as the bottom electrode 435 or of a material which is different from that of the bottom electrode 435.

Still referring to FIG. 7C, a mask pattern 465 is formed on the conductive layer 450.

Referring to FIG. 7D, the conductive layer 450 and the phase-change material layer 440 are patterned using the mask pattern 435 to expose the second interlayer dielectric 425. The mask pattern 465 is then removed. In this manner, a phase-change material pattern 445 and a top electrode 455 are sequentially formed on the second interlayer dielectric 425.

Referring to FIG. 7E, a third interlayer dielectric 480 is formed on the resultant structure. After patterning the third interlayer dielectric 480, an interconnection plug 485 is formed to be electrically connected to the top electrode 455. Other and subsequent interconnection processes may be performed.

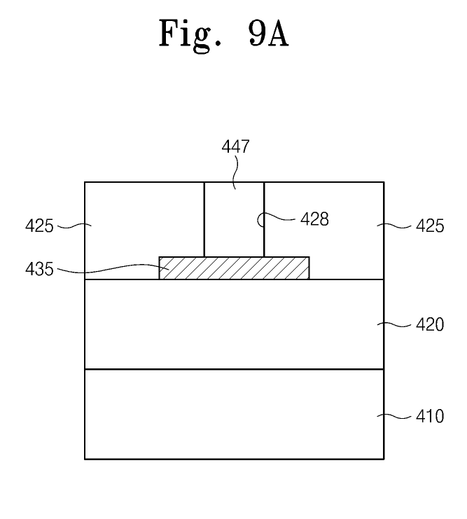

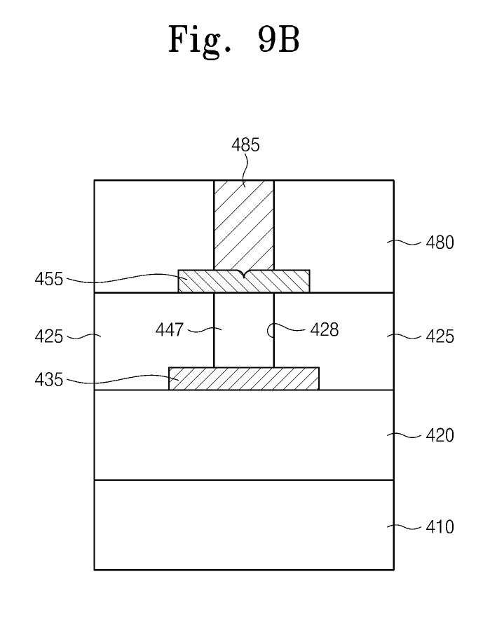

A method of fabricating a memory device including a chalcogenide thin film according to another exemplary embodiment of the present invention will now be described below in detail with reference to the cross-sectional examples of FIGS. 9A and 9B.

Referring to FIG. 9A, in the resultant structure of FIG. 7B, the phase-change material layer 440 is planarized down to a top surface of the second interlayer dielectric 425 to form a phase-change material pattern 447 within the opening 428.

Referring to FIG. 9B, a top electrode 455 is formed on the phase-change material pattern 447, and a third interlayer dielectric 480 is formed on the resultant structure. After patterning the third interlayer dielectric 480, an interconnection plug 485 is formed to be electrically connected to the top electrode 455.

As described above, by exposing a substrate to a germanium source and an antimony source, a germanium thin film that is substantially free of antimony can be formed on the substrate. Further, by then sequentially supplying a tellurium source and an antimony source, a polynary thin film can be formed which exhibits favorable properties in which three kinds of atoms can coexist in a single layer according to a desired composition ratio. A phase-change material layer having favorable step coverage characteristics and a uniform composition ratio can thus be formed.

Although the present invention has been described in connection with the exemplary embodiment of the present invention illustrated in the accompanying drawings, it is not limited thereto. It will be apparent to those skilled in the art that various substitutions, modifications and changes may be made without departing from the scope and spirit of the invention.

What is claimed is:

1. A method of forming a chalcogenide film, comprising:
forming a germanium film on a substrate by exposing the substrate to a germanium source and a first antimony source; and
growing a polynary film from the germanium film by exposing the germanium film to at least one of a tellurium source and a second antimony source.

2. The method as set forth in claim 1, wherein the germanium film that is formed by exposing the substrate to the germanium source and the first antimony source is a unary germanium film that is substantially free of antimony.

3. The method as set forth in claim 2, wherein the substrate is contained in a chamber, and wherein forming the germanium film comprises supplying the germanium source and supplying the first antimony source into the chamber, wherein a supply amount of the germanium source is greater than a supply amount of the first antimony source.

4. The method as set forth in claim 1, wherein the substrate is contained in a chamber, and wherein forming the germanium film comprises simultaneously supplying the germanium source and the first antimony source into the chamber.

5. The method as set forth in claim 1, wherein growing the polynary film comprises forming a binary film which includes germanium and tellurium on the substrate by exposing the germanium film to the tellurium source.

6. The method as set forth in claim 5, wherein growing the polynary film comprise forming a ternary film including germanium, tellurium, and antimony on the substrate by exposing the binary film to the second antimony source.

7. A method of fabricating a memory device, comprising forming an insulating layer which includes an opening that exposes a bottom electrode, forming a chalcogenide pattern which fills the opening, and forming a top electrode on the chalcogenide pattern, wherein forming the chalcogenide pattern comprises:
forming a germanium film within the opening by exposing the opening to a germanium source and a first antimony source; and
growing a polynary film from the germanium film by exposing the germanium film to at least one of a tellurium source and a second antimony source.

8. The method as set forth in claim 7, wherein forming the chalcogenide pattern and forming the top electrode on the chalcogenide pattern comprise:
forming a chalcogenide film on the insulating layer with the opening;
forming a conductive layer on the chalcogenide film; and
patterning the conductive layer and the chalcogenide film to expose the insulating layer.

9. The method as set forth in claim 7, wherein forming the chalcogenide pattern comprises:
forming a chalcogenide film on the insulating layer with the opening; and
planarizing the chalcogenide film down to a top surface of the insulating layer.

10. The method as set forth in claim 7, wherein growing the polynary film comprises:
forming a binary film including germanium and tellurium within the opening by exposing the germanium film to the tellurium source; and
forming a ternary thin film including germanium, tellurium, and antimony within the opening by exposing the binary film to the second antimony source.
